(19) United States
(12) Patent Application Publication
(10) Pub. No.: US 2010/0001337 A1
(43) Pub. Date: Jan. 7, 2010

(54) Semiconductor memory device

(75) Inventors: Han-Soo Kim, Suwon-si (KR); Jae-Hoon Jang, Seongnam-si (KR); Hoo-Sung Cho, Yongin-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/456,537

(22) Filed: Jun. 18, 2009

(30) Foreign Application Priority Data
Jul. 4, 2008 (KR) 10-2008-0065118

(51) Int. Cl. H01L 29/792; H01L 29/66

(52) U.S. Cl. 257/324; 257/390; 257/E29.166; 257/E29.309

(57) ABSTRACT

A semiconductor memory device includes: sequentially stacked first and second semiconductor layers; at least one first memory transistor disposed on the first semiconductor layer; and at least one second memory transistor disposed on the second semiconductor layer, wherein a gate electrode of the first memory transistor has a broader width than that of the second memory transistor.

### CROSS-REFERENCE TO RELATED APPLICATIONS

This U.S. non-provisional patent application claims priority under 35 U.S.C. §119 of Korean Patent Application No. 10-2008-0065118, filed on Jul. 4, 2008, the entire contents of which are hereby incorporated by reference.

### BACKGROUND

Exemplary embodiments described herein relate to a semiconductor memory device.

It is required that the degree of integration in a semiconductor device be increased in order to provide improved device performance and reduced cost. In a semiconductor memory device, since the degree of integration is a very important factor for determining product price, a higher degree of integration is required. In the case of a typical two-dimensional or plane semiconductor memory device, since its degree of integration is largely determined by an area occupied by a unit memory cell, techniques used to form fine patterns have an effect on the integration degree and, therefore, the device cost. However, since expensive equipment is required for pattern miniaturization, even if the integration degree of a two-dimensional semiconductor memory device is increased, the semiconductor device is still under certain restrictions.

### SUMMARY

Exemplary embodiments provide a semiconductor memory device with increased degree of integration.

Exemplary embodiments also provide a semiconductor memory device capable of reducing variations in characteristics of transistors according to a time difference in exposure to a thermal environment.

Embodiments of the present invention provide a semiconductor memory device including: sequentially stacked first and second semiconductor layers; at least one first memory transistor disposed on the first semiconductor layer; and at least one second memory transistor disposed on the second semiconductor layer, wherein a gate electrode of the first memory transistor has a broader width than that of the second memory transistor.

In some embodiments, a channel length of the first memory transistor is the same as that of the second memory transistor.

In some embodiments, the semiconductor memory device further includes: a first function transistor disposed on the first semiconductor layer to control an electrical connection for the first memory transistor; and a second function transistor disposed on the second semiconductor layer to provide the same function as the first function transistor, wherein a gate electrode of the first function transistor has a broader width than that of the second function transistor.

In some embodiments, a channel length of the first function transistor is substantially the same as that of the second function transistor.

In some embodiments, the semiconductor memory device further includes: a first common source line and a first bit line plug contacting with the first semiconductor layer; and a second common source line and a second bit line plug contacting with the second semiconductor layer. At least one of the first memory transistors includes a plurality of first memory transistors connected in series to constitute a first string structure; at least one of the second memory transistors includes a plurality of second memory transistors connected in series to constitute a second string structure; the first function transistor is used as a selection transistor to control an electrical connection between the first string structure and the first common source line and between the first string structure and the first bit line plug; and the second function transistor is used as a selection transistor to control an electrical connection between the second string structure and the second common source line and between the second string structure and the second bit line plug.

Other embodiments of the present invention provide a semiconductor memory device which includes: sequentially stacked first and second semiconductor layers; a first string structure including a pair of first selection transistors and a plurality of first memory transistors interposed therebetween, the first string structure being disposed on the first semiconductor layer; and a second string structure including a pair of second selection transistors and a plurality of second memory transistors interposed therebetween, the second string structure being disposed on the second semiconductor layer, wherein a length of the first string structure is longer than that of the second string structure.

In some embodiments, a gate electrode of the first memory transistor is longer than that of the second memory transistor.

In some embodiments, a channel length of the first memory transistor is substantially the same as that of the second memory transistor.

In some embodiments, a pitch of the first memory transistor is longer than that of the second memory transistor.

In some embodiments, a gate electrode of the first selection transistor is longer than that of the second selection transistor.

In some embodiments, a channel length of the first selection transistor is substantially the same as that of the second selection transistor.

In some embodiment, semiconductor memory device further includes: a first common source line and a first bit line plug connected to both ends of the first string structure, respectively; and a second common source line and a second bit line plug connected to both ends of the second string structure, respectively. The first bit line plug is spaced apart from the second semiconductor layer and penetrates the second semiconductor layer. The second bit line plug is disposed between one of the second selection transistors and the first bit line plug.

In some embodiments, a difference between the length of the second string structure and the length of the first string structure is less than or identical to two times of a distance between central axes of the first and second bit line plugs.

In some embodiments, the first bit line plug includes: a lower plug disposed at one side of the first selection transistor; and an upper plug penetrating the second semiconductor layer to be in contact with the lower plug.

In some embodiments, the first and second memory transistors have the same pitch and the gate electrodes of the first and second selection transistors have respectively different lengths.

In some embodiments, the first and second memory transistors include a charge storage layer.

### BRIEF DESCRIPTION OF THE DRAWINGS

The foregoing and other features and advantages of the invention will be apparent from the more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIGS. 1 through 7 are sectional views illustrating semiconductor memory devices according to embodiments of the present invention.

FIG. 8 is a cross-sectional view illustrating memory transistors of a semiconductor memory device according to one embodiment of the present invention.

FIG. 9 is a block diagram illustrating one example of a memory card including a flash memory device according to the present invention.

FIG. 10 is a block diagram illustrating an information processing system including a flash memory system according to the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be construed as limited to the embodiments set forth herein. Rather, these embodiments are provided so that this description will be thorough and complete, and will fully convey the scope of the present invention to those skilled in the art. It will be understood that although the terms first and second are used herein to describe various elements, these elements should not be limited by these terms. These terms are only used to distinguish one element from another element. It will also be understood that when a layer (or film) is referred to as being ‘on’ another layer or substrate, it can be directly on the other layer or substrate, or intervening layers may also be present. In the figures, the dimensions of layers and regions are exaggerated for clarity of illustration.

A three-dimensional NAND flash memory device, in which flash memory cells are three-dimensionally arranged to constitute a NAND type cell array, will be described as one example to describe inventive concepts of the present invention. However, the technical scope of the present invention is not limited to the illustrated three-dimensional NAND flash memory device and may be applied to various semiconductor devices including three-dimensionally arranged memory cells. For example, the technical scope of the present invention may be realized using a three-dimensional NOR flash memory device. Additionally, for a concise description, a three-dimensional semiconductor memory device including two semiconductor layers is described as an example, but the technical ideas of the present invention may also be applied to a three-dimensional semiconductor device including at least three semiconductor layers.

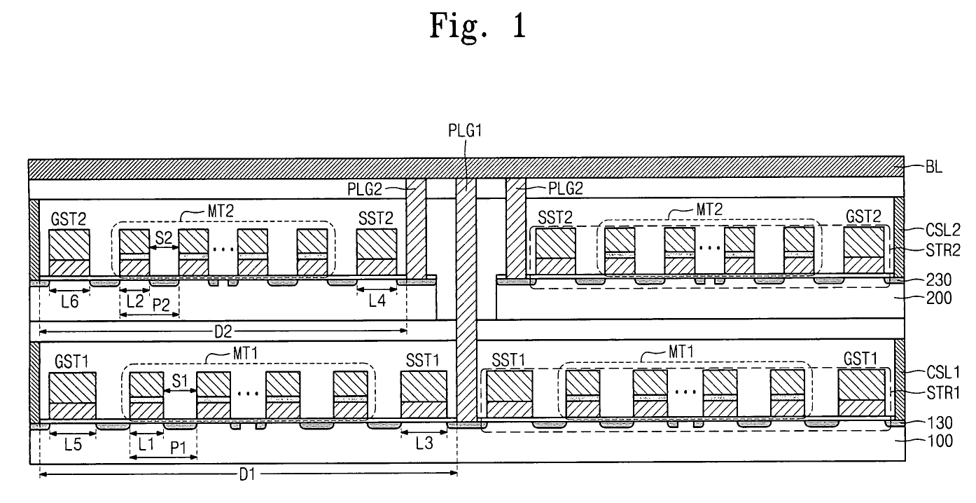

FIGS. 1 through 7 are sectional views illustrating semiconductor memory devices according to embodiments of the present invention.

Referring to FIG. 1 through 7, the semiconductor memory devices according to these embodiments includes a first semiconductor layer 100 and a second semiconductor layer 200, which are stacked. The first semiconductor layer 100 may be a semiconductor wafer, and the second semiconductor layer 200 may be a semiconductor layer formed through one of an epitaxial process, a wafer bonding process, and a deposition process. The first and second semiconductor layers 100 and 200 may be formed of the same kind of a semiconductor material and may be spaced apart from each other.

A first string structure STR1 is formed on the first semiconductor layer 100, and a second string structure STR2 is formed on the second semiconductor layer 200. The first string structure STR1 may include a pair of first selection transistors SST1 and GST1 and a plurality of first memory transistors MT1 interposed therebetween. The second string structure STR2 may include a pair of second selection transistors SST2 and GST2 and a plurality of second memory transistors MT2 interposed therebetween.

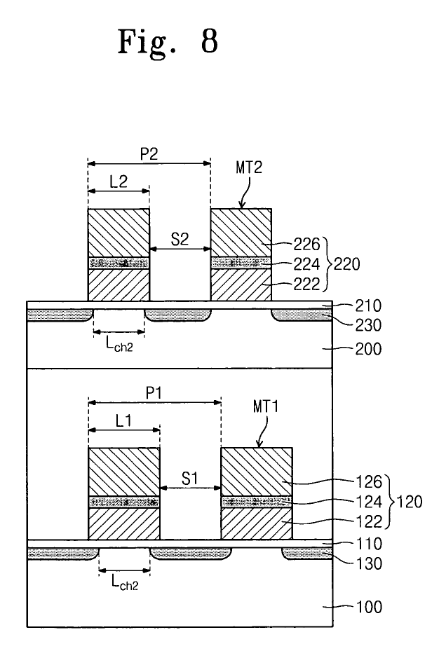

Each of the first and second memory transistors MT1 and MT2 may be a transistor including an information storage element. For example, the information storage element may be an electrically isolated conductor (i.e., a floating gate electrode). In more detail, as illustrated in FIG. 8, the first and second memory transistors MT1 and MT2 may have a gate structure including tunnel insulation layers 110 and 210, floating gate electrodes 122 and 222, and gate interlayer insulation layers 124 and 224, which are sequentially stacked between the semiconductor layer 100 and 200 and word lines 126 and 226. According to a modified embodiment of the present invention, the first and second memory transistors MT1 and MT2 may have a gate structure including a conductive or insulating charge trap layer, although that structure is not illustrated in the drawings.

The first and second selection transistors SST1, GST1, SST2, and GST2 may have substantially the same stacking structure as the first and second memory transistors MT1 and MT2 except that in the first and second selection transistors SST1, GST1, SST2, GST2, the word lines 126 and 226 are in direct contact with the floating gate electrodes 122 and 222. The first and second selection transistors SST1, GST1, SST2, and GST2 may have a broader width than the first and second memory transistors MT1 and MT2.

A first common source line CSL1 and a first bit line plug PLG1 are disposed at the ends of the first string structure STR1 to be in contact with impurity regions 130 of the pair of first selection transistors SST1 and GST1. A second common source line CSL2 and a second bit line plug PLG2 are disposed at the ends of the second string structure STR2 to be in contact with impurity regions 230 of the pair of second selection transistors SST2 and GST2. In this embodiment, the first memory transistors MT1 and the first selection transistors SST1 and GST1 are disposed to connect the first common source line CSL1 and the first bit line plug PLG1 in series, and the second memory transistors MT2 and the second selection transistors SST2 and GST2 are disposed to connect the second common source line CSL2 and the second bit line plug PLG2 in series. The first and second bit line plugs PLG1 and PLG2 may be commonly connected to one of the bit lines BL crossing over the word lines 126 and 226.

According to this embodiment, the first bit line plug PLG1 may be formed to penetrate the second semiconductor layer 200. Furthermore, the first bit line plug PLG1 may be formed spaced apart from the second semiconductor layer 200 in order to prevent an electric short with a well region of the second semiconductor layer 200. The second bit line plug PLG2 may be interposed between the first bit line plug PLG1 and a gate electrode of the second selection transistor SST2. As a result, the interval D1 (i.e., the length of the first string structure STR1) between the first bit line plug PLG1 and the first common source line CSL1 may be longer than the interval D2 (i.e., the length of the second string structure STR2) between the second bit line plug PLG2 and the second common source line CSL2. According to one embodiment, the interval difference (i.e., D1-D2) may be substantially identical to or less than two times the distance between the center axes of the first and second bit line plugs PLG1 and PLG2.

Since the first and second string structures STR1 and STR2 are sequentially formed, transistors constituting the first and second string structures STR1 and STR2 may have non-uniform electrical characteristics. For example, since the first string structure STR1 is exposed to a thermal atmosphere during forming of the second semiconductor layer 200 and forming of the second string structure STR2, it may be exposed to a thermal environment longer than the second string structure STR2. A time difference of exposure to this thermal environment may lead to non-uniformity in a physical structure between a transistor of the first string structure STR1 and a transistor of the second string structure STR2 corresponding to the first string structure STR1.

In more detail, as well known, heat energy may cause diffusion of impurities in the first and second semiconductor layers 100 and 200. This impurity diffusion may reduce the channel length of a transistor. The first and second string structures STR1 and STR2 may be formed through the same mask and manufacturing processes. Accordingly, as illustrated in FIG. 8, the channel length L_{ch1} of a transistor constituting the first string structure STR1 (which is exposed to a thermal environment longer than the second string structure STR2) may be shorter than the channel length L_{ch2} of a transistor constituting the second string structure STR2. Specifically, as a time difference in exposure to a thermal environment is increased, the difference L_{ch2}-L_{ch1} between these channel lengths is also increased. Therefore, a short channel effect may occur more prevalently in transistors constituting the first string structure STR1.

According to the embodiments of the present invention, the difference (i.e., D1-D2) between the lengths of the first and second string structures STR1 and STR2 can be used in order to improve characteristics of transistors constituting the first string structure STR1 or in order to overcome technical limitations caused by a time difference of exposure to the above-mentioned thermal environment.

In more detail, referring to Table 1, as illustrated in FIGS. 1 through 6, the gate pattern 120 of the first memory transistors MT1 may have a longer line width than the gate pattern 220 of the second memory transistors MT2. The difference L1-L2 between the line widths of the gate patterns 120 and 220 may be selected to compensate for a difference between the channel lengths of the first and second memory transistors MT1 and MT2 according to a time difference of exposure to a thermal environment. For example, the line width difference L1-L2 may be substantially identical to two times the diffusion length of impurities caused by a time difference of exposure to a thermal environment. In this case, the channel lengths L_{ch2} and L_{ch1} of the first and second memory transistors MT1 and MT2 according to the present invention may become identical to each other (i.e., L_{ch2}=L_{ch1}). The line widths L1 and L2 of the gate patterns 120 and 220 for satisfying this condition can be selected through empirical or theoretical methods. Additionally, the first memory transistors MT1 may have a longer pitch than the second memory transistors MT2.

Moreover, as illustrated in FIGS. 1, 3, 4, and 5, one of the first selection transistors MT1 may include a gate pattern having a broader line width than the corresponding second selection transistor MT2. For example, as illustrated in FIGS. 1, 3, and 5, a gate pattern of the first selection transistor (hereinafter, referred to as a first string selection transistor SST1) adjacent to the first bit line plug PLG1 may be formed to have a longer line width than a gate pattern of the second selection transistor (hereinafter, referred to as a second string selection transistor SST2) adjacent to the second bit line plug PLG2 (i.e., L3>L4). The line widths L3 and L4 can be selected to compensate for a difference between the channel lengths of the first and second string selection transistors SST1 and SST2.

According to another embodiment of the present invention, as illustrated in FIGS. 1, 4, and 5, a gate pattern of the first selection transistor (hereinafter, referred to as a first ground selection transistor GST1) adjacent to the first common source line CSL1 can be formed to have a longer line width than a gate pattern of the second selection transistor (hereinafter, referred to as a second ground selection transistor GST2) adjacent to the second common source line CSL2 (i.e., L5>L6). The line widths L5 and L6 may be selected to compensate for a difference between the channel lengths of the first and second ground selection transistors GST1 and GST2.

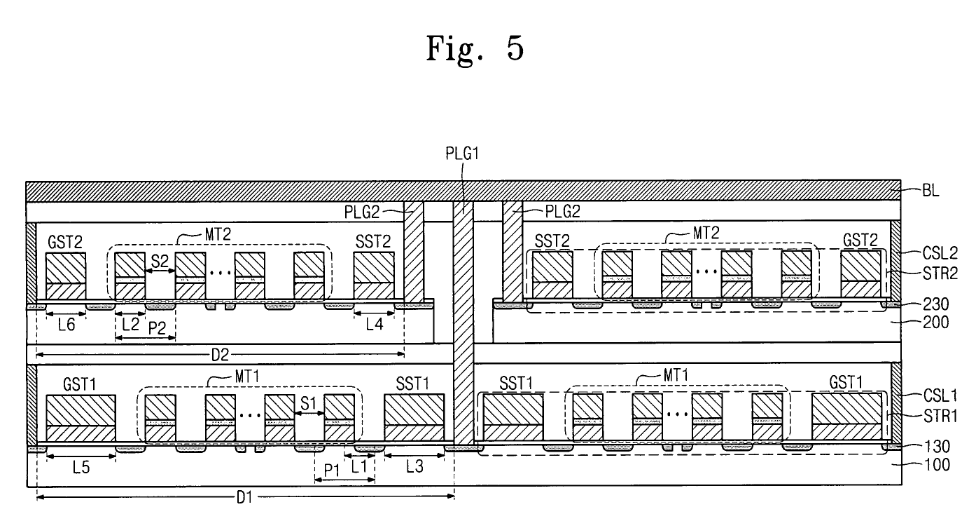

According to another embodiment, as illustrated in FIGS. 1 and 5, gate patterns of the first selection transistors SST1 and GST1 can be formed to have longer line widths than those of the second selection transistors SST2 and GST2 (i.e., L3>L4 and L5>L6).

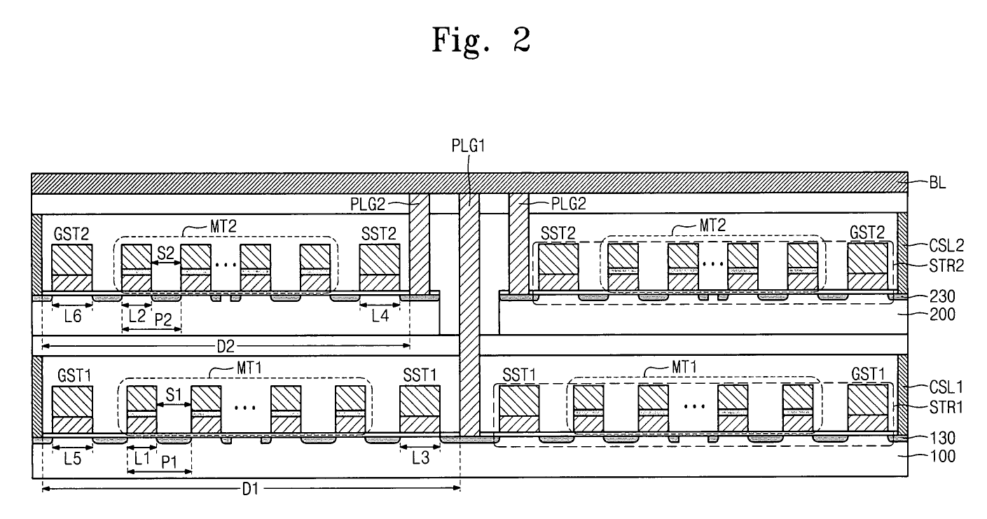

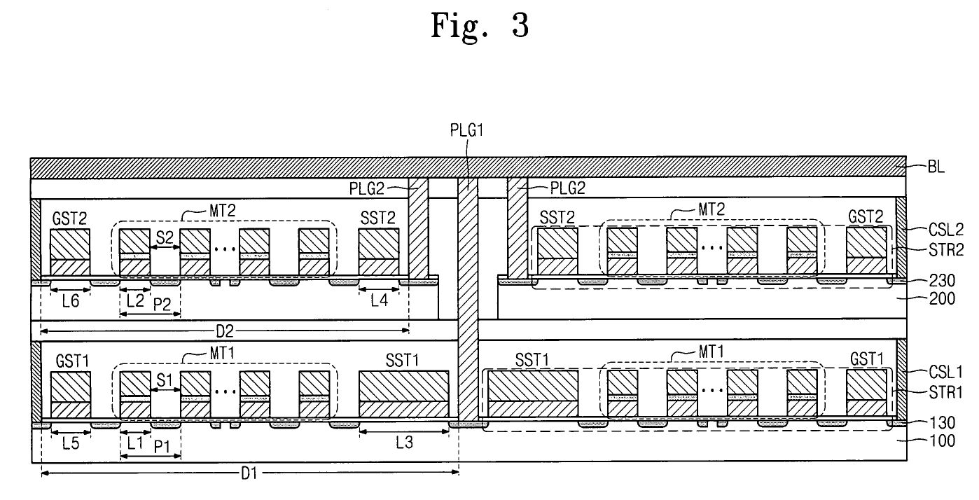

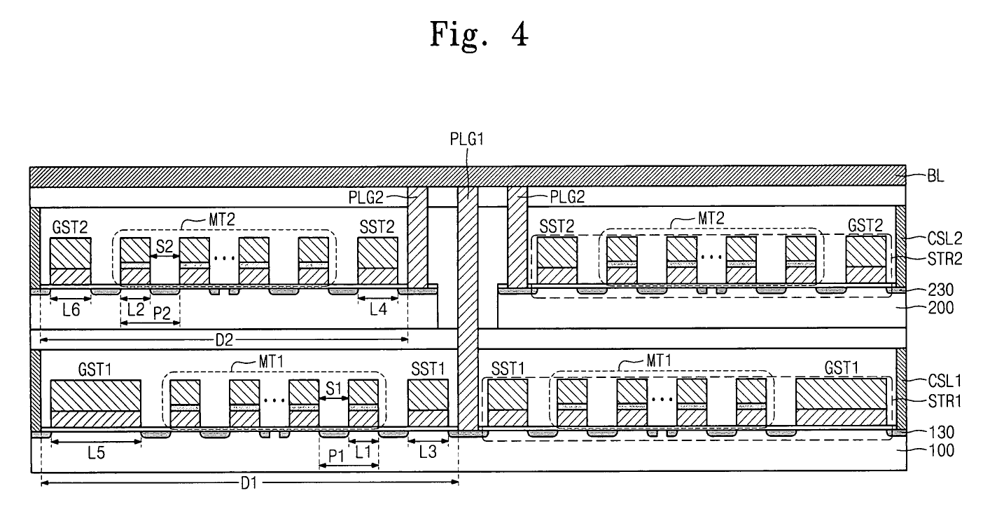

TABLE 1

| | | | | | |
|---|---|---|---|---|---|
| First Embodiment | L1 > L2 | L3 > L4 | L5 > L6 | P1 > P2 | FIGS. 1 |
| | | | | | and 6 |
| Second Embodiment | L1 > L2 | L3 = L4 | L5 = L6 | P1 > P2 | FIG. 2 |
| Third Embodiment | L1 = L2 | L3 > L4 | L5 = L6 | P1 = P2 | FIGS. 3 |
| | | | | | and 7 |
| Fourth Embodiment | L1 = L2 | L3 = L4 | L5 > L6 | P1 = P2 | FIG. 4 |
| Fifth Embodiment | L1 = L2 | L3 > L4 | L5 > L6 | P1 = P2 | FIG. 5 |
| Six Embodiment | L1 > L2 | L3 = L4 | L5 > L6 | P1 > P2 | FIG. 4 |
| Seventh Embodiment | L1 > L2 | L3 > L4 | L5 = L6 | P1 > P2 | FIG. 5 |

L1: Gate Line Width Of First Memory Transistor
L2: Gate Line Width Of Second Memory Transistor
L3: Gate Line Width Of First String Selection Transistor
L4: Gate Line Width Of Second String Selection Transistor
L5: Gate Line Width Of First Ground Selection Transistor
L6: Gate Line Width Of Second Ground Selection Transistor
P1: Pitch Of First Memory Transistor
P2: Pitch Of Second Memory Transistor

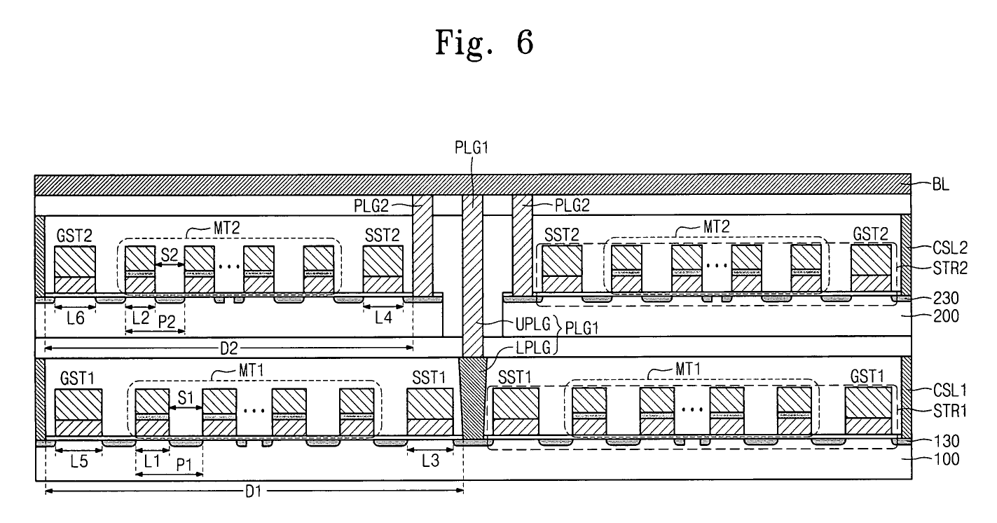

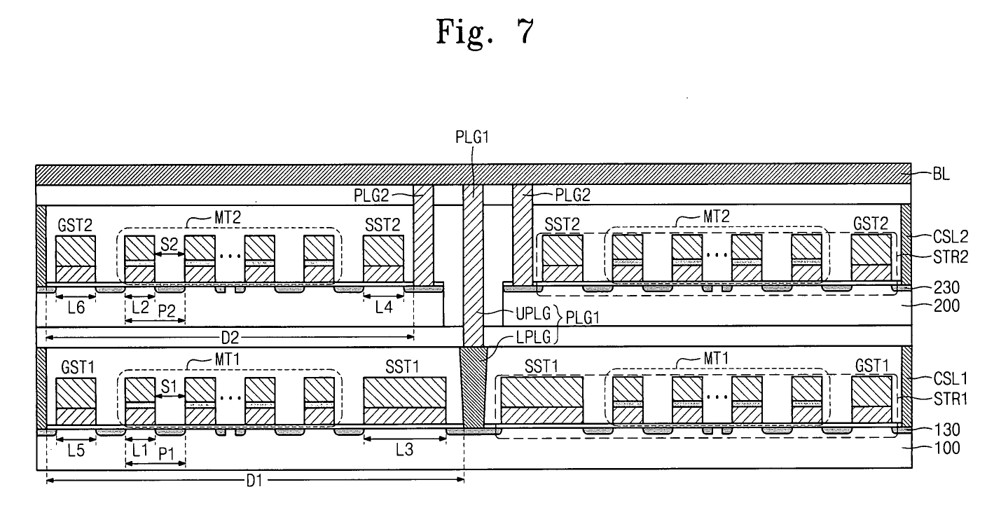

According to a modified embodiment of the present invention, as illustrated in FIGS. 6 and 7, the first bit line plug PLG1 penetrates a lower plug LPLG contacting with the first semiconductor layer 100 and the second semiconductor layer 200 to include an upper plug ULPG stacked on the lower plug LPLG. According to one embodiment, the lower plug LPLG may be formed during the forming of the first common source line CSL1. According to another embodiment, the lower plug LPLG may be formed during forming of an additional plug. The upper plug ULPG of the modified embodiments may be formed shorter by the lower plug LPLG than the first bit line plug PLG1 of the embodiments described with reference to FIGS. 1 through 5. Although not illustrated in the drawings, the embodiments described with reference to FIGS. 2, 4, and 5 may be modified to include the lower and upper plugs LPLG and ULPG.

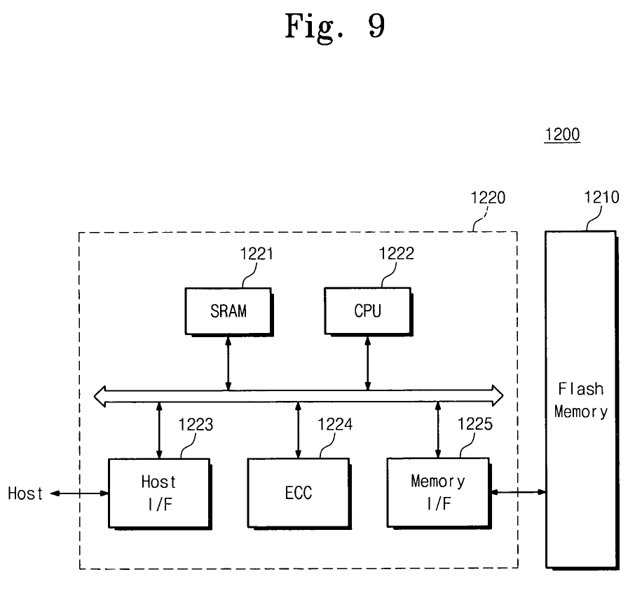

FIG. 9 is a block diagram illustrating one example of a memory card 1200 including a flash memory device according to embodiments of the present invention. Referring to FIG. 9, the memory card 1200 for supporting a high capacity of data storage includes a flash memory device 1210 according to embodiments of the present invention. The memory card 1200 includes a memory controller 1220 for general data exchange between a host and the flash memory device 1210.

SRAM 1221 is used as an operating memory of a central processing unit (CPU) 1222. A host interface (I/F) 1223 includes a data exchange protocol of a host connected to the memory card 1200. An error correction code (ECC) 1224 detects and corrects an error included in data read from the multi-bit flash memory device 1210. A memory interface (I/F) 1225 may interface with the flash memory device 1210 of the present invention. The CPU 1222 performs general control operations for data exchange of the memory controller 1220. Although not illustrated in the drawings, it is apparent to those skilled in the art that the memory card 1200 may further include ROM (not shown) for storing code data to interface with the host.

According to a flash memory device, a memory card, or memory system, a more reliable memory system can be provided through the flash memory device 1210 having the improved erasing characteristic of dummy cells. Specifically, the flash memory device of the present invention such as a recent solid state disk (SSD), which is actively under development, may be provided in the memory system. In this case, errors caused from dummy cells can be prevented to realize a highly reliable memory system.

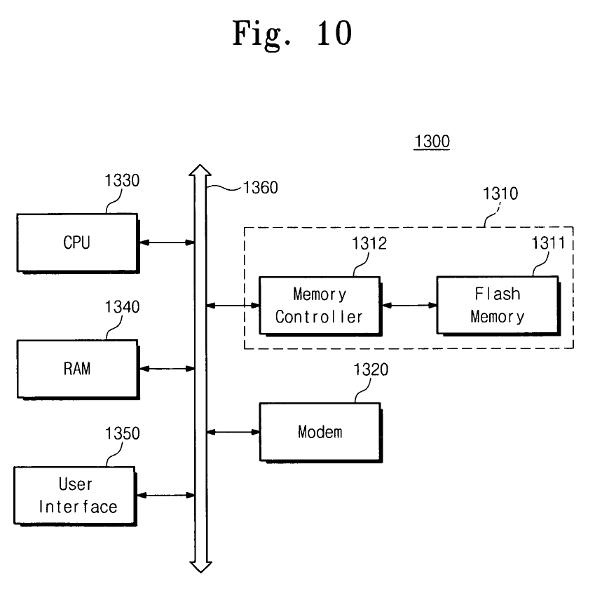

FIG. 10 is a block diagram illustrating an information processing system 1300 including a flash memory system 1310 according to embodiments of the present invention. Referring to FIG. 10, the flash memory system 1310 is mounted in the information processing system 1300 such as a mobile device or a desktop computer. The information processing system 1300 according to the present invention includes a modem 1320 connected to the flash memory system 1310 via a system bus 1360, CPU 1330, RAM 1340, and a user interface 1350. The flash memory system 1310 may have substantially the same configuration as the above-described memory system or flash memory system. The flash memory system 1310 stores data processed by the CPU 1330 or data inputted from the exterior. The flash memory system 1310 may include SSD. In this case, the information processing system 1300 can stably store high capacity data in the flash memory system 1310. As its reliability is increased, the flash memory system 1310 may save resources consumed for an error correction process and thus provides a high speed of data exchange function to the information processing system 1300. Although not illustrated in the drawing, it is apparent to those skilled in the art that the information processing system 1300 may further include an application chipset, a camera image processor (CIS), and an input/output device.

The flash memory device or the memory system according to the present invention may be mounted using various kinds of packages. Examples of the various packages include package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline (SOIC), shrink small outline package (SSOP), thin small outline (TSOP), thin quad flatpack (TQFP), system in package (SIP), multi chip package (MCP), wafer-level fabricated package (WFP), wafer-level processed stack package (WSP), etc.

According to the present invention, transistors having the same function, disposed on mutually different layers, are formed to have mutually different gate widths in order to substantially obtain the same channel length, regardless of a time difference in exposure to a thermal environment. For example, the gate width of a transistor disposed on a lower layer may be broader than that of a transistor having the same function and disposed on an upper layer. This gate width difference is selected to compensate for a channel length change caused through a thermal stress difference. As a result, in a semiconductor memory device according to the present invention, characteristic changes of memory cell transistors can be reduced. Furthermore, since transistors disposed on the lower layer have the increased gate line width, the semiconductor memory device according to the present invention may have an improved short channel effect.

The above-described subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A semiconductor memory device comprising:
sequentially stacked first and second semiconductor layers;
at least one first memory transistor disposed on the first semiconductor layer; and
at least one second memory transistor disposed on the second semiconductor layer,
wherein a gate electrode of the first memory transistor has a broader width than that of the second memory transistor.

2. The semiconductor memory device of claim 1, wherein a channel length of the first memory transistor is the same as that of the second memory transistor.

3. The semiconductor memory device of claim 1, further comprising:
a first function transistor disposed on the first semiconductor layer to control an electrical connection for the first memory transistor; and
a second function transistor disposed on the second semiconductor layer to provide the same function as the first function transistor,
wherein a gate electrode of the first function transistor has a broader width than that of the second function transistor.

4. The semiconductor memory device of claim 3, wherein a channel length of the first function transistor is substantially the same as that of the second function transistor.

5. The semiconductor memory device of claim 3, further comprising:
a first common source line and a first bit line plug, contacting with the first semiconductor layer; and
a second common source line and a second bit line plug, contacting with the second semiconductor layer,
wherein:
at least one of the first memory transistors includes a plurality of first memory transistors connected in series to constitute a first string structure;
at least one of the second memory transistors includes a plurality of second memory transistors connected in series to constitute a second string structure;
the first function transistor is used as a selection transistor to control an electrical connection between the first string structure and the first common source line and between the first string structure and the first bit line plug; and
the second function transistor is used as a selection transistor to control an electrical connection between the second string structure and the second common source line and between the second string structure and the second bit line plug.

6. A semiconductor memory device comprising:
sequentially stacked first and second semiconductor layers;
a first string structure including a pair of first selection transistors and a plurality of first memory transistors interposed therebetween, the first string structure being disposed on the first semiconductor layer; and
a second string structure including a pair of second selection transistors and a plurality of second memory transistors interposed therebetween, the second string structure being disposed on the second semiconductor layer,
wherein a length of the first string structure is longer than that of the second string structure.

7. The semiconductor memory device of claim 6, wherein a gate electrode of the first memory transistor is longer than that of the second memory transistor in width thereof.

8. The semiconductor memory device of claim 7, wherein a channel length of the first memory transistor is substantially the same as that of the second memory transistor.

9. The semiconductor memory device of claim 6, wherein a pitch of the first memory transistor is longer than that of the second memory transistor.

10. The semiconductor memory device of claim 6, wherein a gate electrode of the first selection transistor is longer than that of the second selection transistor.

11. The semiconductor memory device of claim 10, wherein a channel length of the first selection transistor is substantially the same as that of the second selection transistor.

12. The semiconductor memory device of claim 6, further comprising:
a first common source line and a first bit line plug connected to both ends of the first string structure, respectively; and
a second common source line and a second bit line plug connected to both ends of the second string structure, respectively,
wherein the first bit line plug is spaced apart from the second semiconductor layer and penetrates the second semiconductor layer;
the second bit line plug is disposed between one of the second selection transistors and the first bit line plug.

13. The semiconductor memory device of claim 12, wherein a difference between the length of the second string structure and the length of the first string structure is less than or identical to two times of a distance between central axes of the first and second bit line plugs.

14. The semiconductor memory device of claim 12, wherein the first bit line plug comprises:
a lower plug disposed at one side of the first selection transistor; and
an upper plug penetrating the second semiconductor layer to contact with the lower plug.

15. The semiconductor memory device of claim 6, wherein the first and second memory transistors have the same pitch and the gate electrodes of the first and second selection transistors have respectively different lengths.

16. The semiconductor memory device of claim 6, wherein the first and second memory transistors comprise a charge storage layer.
